(19) United States
(12) Patent Application Publication
(10) Pub. No.: US 2021/0005648 A1
(43) Pub. Date: Jan. 7, 2021

(54) PIXEL ARRAY ELEMENT HAVING ISOLATION STRUCTURE AND METHOD OF MANUFACTURING THE SAME

(71) Applicant: HUAIAN IMAGING DEVICE MANUFACTURER CORPORATION, Huaian (CN)

(72) Inventors: Xinxin Fang, Huaian (CN); Chunqiu Xia, Huaian (CN); Tienchi Ko, Huaian (CN)

(73) Assignee: HUAIAN IMAGING DEVICE MANUFACTURER CORPORATION, Huaian (CN)

(21) Appl. No.: 16/918,625

(22) Filed: Jul. 1, 2020

(30) Foreign Application Priority Data
Jul. 2, 2019 (CN) 201910586975.X

(51) Int. Cl. H01L 27/146

(52) U.S. Cl. CPC H01L 27/1463; H01L 27/14627; H01L 27/14685; H01L 27/14645; H01L 27/14621

(57) ABSTRACT

A pixel array element having an isolation structure, comprising a plurality of groups of pixel cells each including a plurality of pixel cells having different colors, wherein the pixel cells having different colors are alternately arranged such that each pixel cell has a different color from an adjacent pixel cell, and an isolation structure located between the adjacent pixel cells and formed of a color filter material, wherein the color filter material of the isolation structure has a color different from that of the adjacent pixel cell.

### CROSS REFERENCE TO THE RELATED APPLICATION

The present application claims priority to the Chinese application No. 201910586975.X, filed on Jul. 2, 2019, which is herein incorporated by reference in its entirety.

### TECHNICAL FIELD

This disclosure relates to the field of image sensor, and more particularly, to a pixel array element having an isolation structure and a method of manufacturing the same.

### BACKGROUND

The image sensor is used for converting incident light focused on the image sensor into an electrical signal. The image sensor includes a plurality of pixel cells. There is typically an isolation structure between the pixel cells to prevent cross-talk between adjacent pixel cells.

Accordingly, there is a need for improving the existing isolation structures between pixel cells.

### SUMMARY

One of aims of this disclosure is to provide a pixel array element having an isolation structure.

One aspect of this disclosure is to provide a pixel array element having an isolation structure, comprising: a plurality of groups of pixel cells each including a plurality of pixel cells having different colors, wherein the pixel cells having different colors are alternately arranged such that each pixel cell has a different color from an adjacent pixel cell; and an isolation structure located between the adjacent pixel cells and formed of a color filter material, wherein the color filter material of the isolation structure has a color different from that of the adjacent pixel cell.

Further features of this disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of this disclosure and, together with the description, serve to explain the principles of this disclosure.

This disclosure will be better understood according the following detailed description with reference of the accompanying drawings.

FIG. 1 illustrates a plurality of pixel cells having an isolation structure in the prior art.

FIG. 2 illustrates a plurality of pixel cells having an isolation structure according to one or more exemplary embodiments of this disclosure.

FIG. 3 illustrates a group of pixel cells arranged in a Bayer array according to one or more exemplary embodiments of this disclosure.

FIG. 4 illustrates a plurality of pixel cells having an isolation structure formed of a color filter material with a height of 0.3 μm according to one or more exemplary embodiments of this disclosure.

FIG. 5 shows a plurality of pixel cells having an isolation structure formed of tungsten with a height of 0.23 μm.

FIG. 6 is a flowchart of a method of manufacturing a pixel array element according to one or more exemplary embodiments of this disclosure.

FIG. 7a-7h illustrate schematic diagrams of manufacturing a pixel array element according to one or more exemplary embodiments of this disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of this disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to this disclosure. It should be understood by those skilled in the art that, these examples, while indicating the implementations of this disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

The image sensor is used for converting incident light focused on the image sensor into an electrical signal. In general, an image sensor is composed of a plurality of groups of pixel cells each including pixel cells of different colors. The pixel cells having different colors enable different components in incident light to pass through the pixel cells. The plurality of groups of pixel cells are sequentially arranged to form a pixel array element. To avoid crosstalk between different pixel cells caused by the light filtered by the pixel cells of different colors, isolation elements are typically provided between the pixel cells. The isolation elements prevent the light filtered by the pixel cells from being incident into adjacent pixel cells, thereby avoiding crosstalk between the pixel cells.

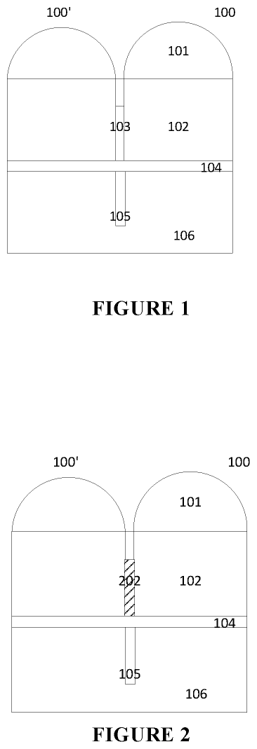

FIG. 1 illustrates a pixel array element having an isolation structure in the prior art. As illustrated, there is an isolation structure 103 between the pixel cell 100 and the pixel cell 100′. FIG. 1 shows only two pixel cells schematically, however the pixel array element may include a plurality of pixel cells. For example, the pixel array element may include a plurality of pixel cells arranged in a Bayer array.

As shown in FIG. 1, the pixel cell 100 includes a photodiode 106, an isolation element 105 between the photodiodes 106, an anti-reflection layer 104 over the photodiode 106, a color filter 102 over the anti-reflection layer 104, an isolation structure 103 between the color filters 102, and a microlens 101 over the color filter 102.

In FIG. 1, the isolation structure 103 is formed of metal tungsten. The isolation structure 103 formed of tungsten prevents light filtered by the pixel cell 100 from being incident into the adjacent pixel cell 100′, thereby preventing crosstalk between the pixel cells.

In general, in the prior art, metal tungsten is used to fabricate the isolation structure between pixel cells. However, the isolation structure formed of tungsten has many defects. On the one hand, an absorptivity of the incident light by metal tungsten is comparatively high, and is usually about 50%. This makes the isolation structure formed of tungsten to absorb a part of the light filtered by the pixel cell while functioning as isolation between the pixel cells, thereby reducing the quantum efficiency and thus the sensitivity of the pixel cell. On the other hand, the use of metal tungsten in fabricating the isolation structure between the pixel cells is prone to cause metal contamination during the fabrication process, which increases the complexity of the fabrication process.

The present application proposes an improvement on the isolation structure between the pixel cells based on at least the above technical problems. According to an embodiment of the present invention, there is provided a pixel array element having an isolation structure, comprising: a plurality of groups of pixel cells each including a plurality of pixel cells having different colors, wherein the pixel cells having different colors are alternately arranged such that each pixel cell has a different color from an adjacent pixel cell; and an isolation structure located between the adjacent pixel cells and formed of a color filter material, wherein the color filter material of the isolation structure has a color different from that of the adjacent pixel cell.

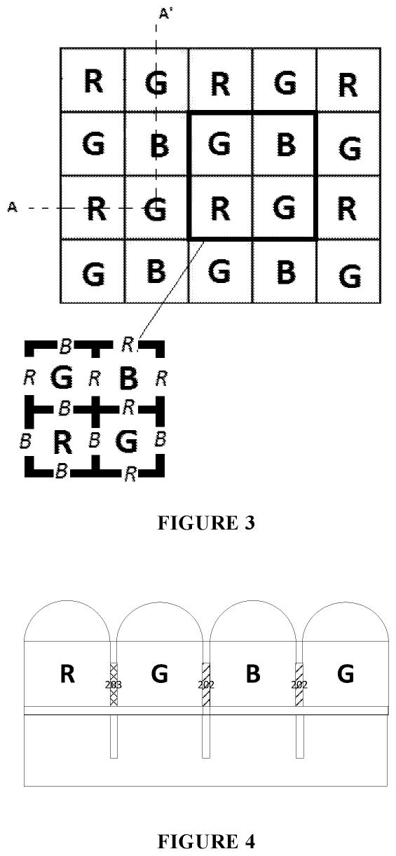

FIG. 2 illustrates a plurality of pixel cells having an isolation structure according to one or more exemplary embodiments of this disclosure. For the purpose of illustration instead of limitation, only two pixel cells are shown, i.e., a blue pixel cell and a green pixel cell. An isolation structure 202 formed of a red color filter material is disposed between the blue pixel cell and the green pixel cell.

Since the blue pixel cell only makes a blue wavelength band component of the incident light pass through, the green pixel cell only makes a green wavelength band component of the incident light pass through, and the isolation structure formed of the red color filter material between the blue pixel cell and the green pixel cell blocks the blue wavelength band component and the green wavelength band component from passing through, the isolation structure can function as isolation between the pixel cells.

Moreover, the light absorptivity by the color filter material is far lower than that of the metal tungsten, thus the isolation element formed from the color filter material does not cause a great loss on the quantum efficiency while functioning as isolation. The color filter material is free from the problem of metal contamination caused by the metal tungsten during the fabrication process, thereby simplifying the processing process.

According to an embodiment of the present invention, each of the plurality of groups of pixel cells includes a plurality of pixel cells arranged in a Bayer array, wherein the isolation structure between the red pixel cell and the green pixel cell is formed of a blue color filter material, and the isolation structure between the green pixel cell and the blue pixel cell is formed of a red color filter material.

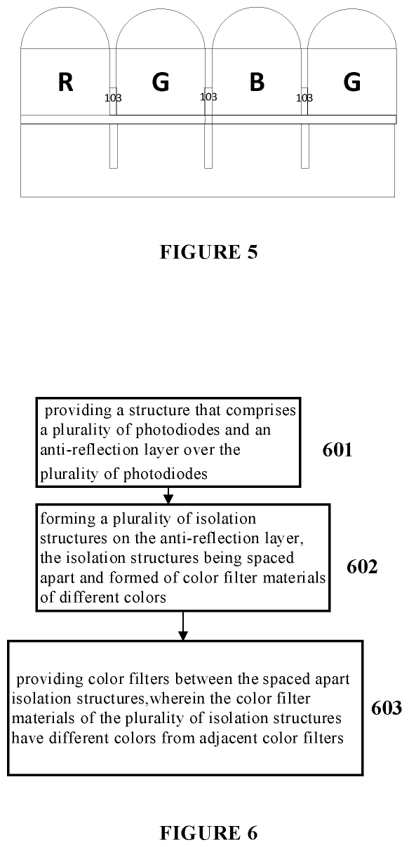

FIG. 3 illustrates a group of pixel cells arranged in a Bayer array according to one or more exemplary embodiments of this disclosure, wherein the isolation structure between the red pixel cell and the green pixel cell is formed of a blue color filter material and the isolation structure between the green pixel cell and the blue pixel cell is formed of a red color filter material. As illustrated in FIG. 3, an isolation structure formed of a blue color filter material is disposed around the red pixel cell R, and an isolation structure formed of a red color filter material is disposed around a blue pixel cell B.

According to one embodiment of the present invention, the height of the isolation structure is chosen such that an increased sensitivity is obtained while maintaining a level of crosstalk between the pixel cells, as compared to the same isolation structure formed of tungsten.

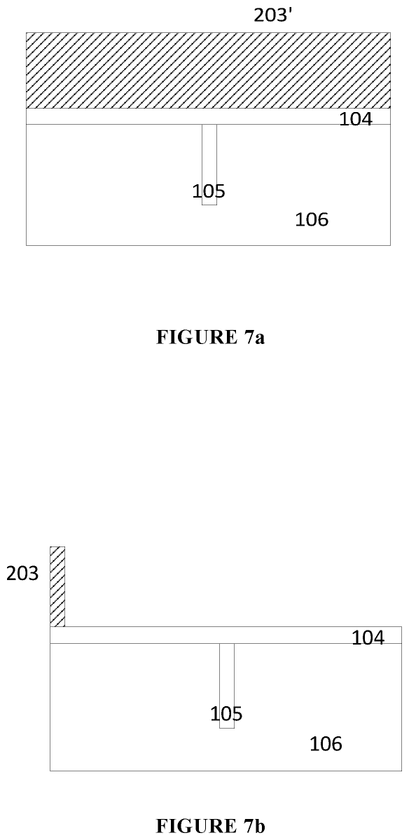

FIG. 4 illustrates a plurality of pixel cells having an isolation structure formed of a color filter material with a height of 0.3 μm according to one or more exemplary embodiments of this disclosure. FIG. 4 show a cross-sectional view along a line A-A′ of the groups of pixel cells arranged in the Bayer array as illustrated in FIG. 3, which sequentially presents a red pixel cell R, a green pixel cell G, a blue pixel cell B, and a green pixel cell G. The isolation structure 203 between the red pixel cell R and the green pixel cell G is formed of a blue color filter material, and the isolation structure 202 between the green pixel cell G and the blue pixel cell B is formed of a red color filter material.

An experiment was made on the group of pixel cells by using an incident light with a wavelength of 550 nm at an incident angle of 0 degree, and a group of pixel cells having an isolation structure formed of tungsten with a height of 0.23 μm was used as the control. The results of the experiment are shown in Table 1.

Since the experiment was made by using the incident light of 550 nm, and the wavelength band is a green light, the quantum efficiency values of the blue pixel cell and the red pixel cell shown in the first and third rows of Table 1 represent the crosstalk condition of the group of pixel cells. Specifically, in this experiment, for the blue pixel cell and the red pixel cell, the lower the quantum efficiency value, the lower the crosstalk between the pixel cells. As can be seen from the table, as compared with the pixel cells having the isolation structure formed of tungsten, the quantum efficiency values of the blue pixel cell and the red pixel cell having the isolation structure formed of the color filter material substantially maintain unchanged. That is, as compared with the pixel array element having the isolation structure formed of tungsten, the pixel array element having the isolation structure formed of the color filter material maintains the level of crosstalk between the pixel cells. In this disclosure, maintaining the level of crosstalk means that an increase in the quantum efficiency value representing the level of crosstalk does not exceed 0.015.

For example, for the blue pixel cell, as compared with a pixel cell having the same isolation structure formed of tungsten, the pixel cell having the isolation structure formed of the color filter material has an increase in quantum efficiency value of only 0.001. For the red pixel cell, as compared with a pixel cell having the same isolation structure formed of tungsten, the pixel cell having the isolation structure formed of the color filter material has an increase in quantum efficiency value of only 0.001. That is, the level of crosstalk is maintained between the pixel cells having the isolation structure formed of the color filter material, as compared with the pixel cell having the same isolation structure formed of tungsten.

Since the experiment was made using the incident light of 550 nm, and the wavelength band is green light, the quantum efficiency value of the green pixel cell shown in the second row of Table 1 represents a sensitivity of the group of pixel cells to green light. In the above experiment, for the green pixel cell, the quantum efficiency value was improved compared to the pixel cell having the isolation structure formed of tungsten. As can be seen from Table 1, as compared to the pixel cell having the isolation structure formed of tungsten, the quantum efficiency value of the pixel cell having the isolation structure formed of the color filter material with a height of 0.3 μm was increased by 0.009.

TABLE 1

| | | 0.3 μm-color |
|---|---|---|
| | | filter |
| | 0.23 μm-tungsten | material |
| Quantum efficiency (blue pixel cell) | 0.046 | 0.047 |
| Quantum efficiency (green pixel cell) | 0.62 | 0.629 |
| Quantum efficiency (red pixel cell) | 0.014 | 0.015 |

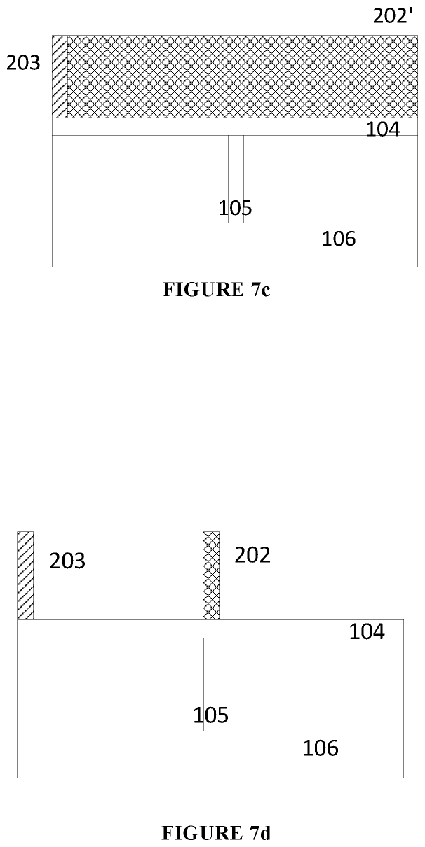

FIG. 5 shows a group of pixel cells having an isolation structure formed of tungsten with a height of 0.23 μm.

According to an embodiment of this disclosure, an experiment was made by using a group of pixel cells having the following isolation structure: an isolation structure formed of a color filter material with a height of 0.2 μm, an isolation structure formed of a color filter material with a height of 0.3 μm, an isolation structure formed of a color filter material with a height of 0.4 μm, and an isolation structure formed of a color filter material with a height of 0.5 a m. And a group of pixel cells having an isolation structure formed of tungsten with a height of 0.23 μm was used as a control.

The experiment was made on the above-described group of pixel cells by using the incident light having a wavelength of 550 nm at an incident angle of 20 degrees. The results of the experiment are shown in Table 2. Table 2 shows a comparison of quantum efficiency values between the pixel cell having the isolation structure formed of tungsten and the pixel cells having the isolation structure formed of the color filter material with different heights.

In Table 2, the first row represents quantum efficiency values of blue pixel cells having the isolation structure formed of the color filter material with different heights. In Table 2, the second row represents quantum efficiency values of green pixel cells having the isolation structure formed of the color filter material with different heights. In Table 2, the third row represents quantum efficiency values of red pixel cells having the isolation structure formed of the color filter material with different heights.

Since the experiment was made using the incident light of 550 nm, and the wavelength band is green light, the quantum efficiency values of the blue pixel cell and the red pixel cell shown in the first and third rows of Table 2 represent the crosstalk condition of the group of pixel cells. Specifically, for the blue and red pixel cells, the lower the quantum efficiency value, the lower the crosstalk between the pixel cells.

For example, for the blue pixel cell, as compared to a pixel cell having the same isolation structure formed of tungsten, the pixel cell having the isolation structure formed of the color filter material with a height of 0.2 μm has an increase in the quantum efficiency value of 0.003. For the red pixel cell, as compared to a pixel cell having the same isolation structure formed of tungsten, the pixel cell having the isolation structure formed of the color filter material with a height of 0.2 μm has an increase in the quantum efficiency value of 0.011. That is, a level of crosstalk is maintained between the pixel cells having the isolation structure formed of the color filter material with a height of 0.2 μm, as compared to the pixel cell having the same isolation structure formed of tungsten.

For example, for the blue pixel cell, as compared to the pixel cell having the same isolation structure formed of tungsten, the quantum efficiency value of the pixel cell having the isolation structure formed of the color filter material with a height of 0.3 μm is not increased but decreased by 0.001. For the red pixel cell, as compared to the pixel cell having the same isolation structure formed of tungsten, the quantum efficiency value of the pixel cell having the isolation structure formed of the color filter material with a height of 0.3 μm was increased by 0.008. That is, a level of crosstalk is maintained between the pixel cells having the isolation structure formed of the color filter material with a height of 0.3 μm, as compared to the pixel cell having the same isolation structure formed of tungsten.

Since the experiment was made using the incident light of 550 nm, and the wavelength band is green light, the quantum efficiency value of the green pixel cell shown in the second row of Table 2 represents the sensitivity of the group of pixel cells to green light. As can be learned from the experiment results shown in Table 2, the quantum efficiency value increases as the height of the isolation structure decreases.

In the above experiment, for the green pixel cell having the isolation structure formed of the color filter material, the quantum efficiency value was increased as compared to the pixel cell having the isolation structure formed of tungsten. For example, as compared to the pixel cell having the isolation structure formed of tungsten, the quantum efficiency value of the green pixel cell having the isolation structure formed of the color filter material with a height of 0.2 μm is increased by 0.041, and the quantum efficiency value of the green pixel cell having the isolation structure formed of the color filter material with a height of 0.3 μm is increased by 0.021.

For the group of pixel cells having the isolation structure formed of the color filter material with a height of 0.2 μm, although the quantum efficiency values of the blue pixel cell and the red pixel cell representing the crosstalk condition are slightly increased compared to the group of pixel cells having the isolation structure formed of tungsten, the quantum efficiency value of the green pixel cell representing the sensitivity is increased much more, for example, increased by 0.041. For the group of pixel cells having the isolation structure formed of the color filter material with a height of 0.3 μm, the quantum efficiency value of the green pixel cell representing the sensitivity is increased by 0.021, the quantum efficiency value of the blue pixel cell representing the crosstalk condition is decreased by 0.001, and the quantum efficiency value of the red pixel cell representing the crosstalk condition is increased by 0.008, compared to the pixel cell having the isolation structure formed of tungsten.

Therefore, based on the above experiment results, it is possible to select an optimal height of the isolation structure formed of the color filter material by balancing the quantum efficiency values of the different color pixel cells. For example, in order to balance sensitivity and crosstalk level, an isolation structure formed of a color filter material with a height of 0.3 μm is selected for the isolation structure around the green pixel cell.

TABLE 2

| | | 0.2 μm-color | 0.3 μm-color | 0.4 μm-color | 0.5 μm-color |
|---|---|---|---|---|---|
| | | filter | filter | filter | filter |
| | 0.23 μm-tungsten | material | material | material | material |
| Quantum efficiency | 0.037 | 0.040 | 0.036 | 0.033 | 0.031 |
| (blue pixel cell) | | | | | |
| Quantum efficiency | 0.499 | 0.540 | 0.520 | 0.499 | 0.486 |
| (green pixel cell) | | | | | |
| Quantum efficiency | 0.028 | 0.039 | 0.036 | 0.034 | 0.030 |
| (red pixel cell) | | | | | |

According to an embodiment of the present invention, heights of the isolation structure formed of the red color filter material and the isolation structure formed of the blue color filter material are set to different values, so that maximum sensitivities for the pixel cells of different colors are obtained while maintaining a level of crosstalk between the pixel cells.

The experiment was made on the above-described group of pixel cells using the incident light with a wavelength of 450 nm at an incident angle of 20 degrees. The results of the experiment are shown in Table 3. Table 3 shows a comparison of the quantum efficiency values between the pixel cell having the isolation structure formed of tungsten and the pixel cells having the isolation structure formed of the color filter material of different heights. In Table 3, the first row represents quantum efficiency values of the blue pixel cells having isolation structures of different heights. In Table 3, the second row represents the quantum efficiency values of the green pixel cells having the isolation structures of different heights. In Table 3, the third row represents quantum efficiency values of the red pixel cells having isolation structures of different heights.

Since the experiment was made using the incident light of 450 nm, and the wavelength band is blue light, the quantum efficiency values of the green pixel cells and the red pixel cells shown in the second and third rows of Table 3 represent the crosstalk condition of the group of pixel cells. Specifically, for the green and red pixel cells, the lower the quantum efficiency value, the lower the crosstalk between the pixel cells.

For example, for the green pixel cell, the quantum efficiency value of the pixel cell having the isolation structure formed of the color filter material with a height of 0.2 μm is increased by 0.012 as compared to the pixel cell having the same isolation structure formed of tungsten. For the red pixel cell, the quantum efficiency value of the pixel cell having the isolation structure formed of the color filter material with a height of 0.2 μm is not increased as compared to the pixel cell having the same isolation structure formed of tungsten. That is, a level of crosstalk is maintained between the pixel cells having the isolation structure formed of the color filter material with a height of 0.2 μm, as compared to the pixel cell having the same isolation structure formed of tungsten.

Since the experiment was made using the incident light of 450 nm, and the wavelength band is blue light, the quantum efficiency values of the blue pixel cells shown in the first row of Table 3 represent the sensitivity of the group of pixel cells to blue light. As is clear from the experiment results, the quantum efficiency increases as the height of the isolation structure decreases.

In the above experiment, for the blue pixel cell, the quantum efficiency value of the pixel cell having the isolation structure formed of the color filter material with a height of 0.2 μm was increased by 0.018 compared to the pixel cell having the isolation structure formed of tungsten.

As compared to the pixel cell having the isolation structure formed of tungsten, the quantum efficiency value of the green pixel cell having the isolation structure formed of the color filter material with a height of 0.2 μm was increased by only 0.012, and the quantum efficiency of the red pixel cell having the isolation structure formed of the color filter material with a height of 0.2 μm was not increased, i.e., the crosstalk condition substantially maintains unchanged, and the quantum efficiency value of the blue pixel cell representing the sensitivity was increased by 0.018. Therefore, an isolation structure formed of a color filter material with a height of 0.2 μm may be selected for the isolation structure around the blue pixel cell.

TABLE 3

| | | 0.2 μm-color | 0.3 μm-color | 0.4 μm-color | 0.5 μm-color |
|---|---|---|---|---|---|
| | | filter | filter | filter | filter |
| | 0.23 μm-tungsten | material | material | material | material |
| Quantum efficiency | 0.504 | 0.522 | 0.497 | 0.481 | 0.464 |
| (blue pixel cell) | | | | | |
| Quantum efficiency | 0.051 | 0.063 | 0.065 | 0.068 | 0.068 |
| (green pixel cell) | | | | | |
| Quantum efficiency | 0.031 | 0.031 | 0.032 | 0.033 | 0.035 |
| (red pixel cell) | | | | | |

The experiment was made on the above-described group of pixel cells by using the incident light with a wavelength of 620 nm at an incident angle of 20 degrees. The results of the experiment are shown in Table 4. Table 4 shows a comparison of quantum efficiency values between the pixel cell having an isolation structure formed of tungsten and the pixel cells having the isolation structures formed of the color filter material of different heights.

In Table 4, the first row represents the quantum efficiency of the blue pixel cells having the isolation structures of different heights. In Table 4, the second row represents the quantum efficiency of the green pixel cells having the isolation structures of different heights. In Table 4, the third row represents the quantum efficiency of the red pixel cells having the isolation structures of different heights.

Since the experiment was made by using the incident light of 620 nm, and the wavelength band is red light, the quantum efficiency values of the blue pixel cell and the green pixel cell shown in the first and second rows of Table 4 represent the crosstalk condition of the group of pixel cells. Specifically, for the blue and green pixel cells, the lower the quantum efficiency value, the lower the crosstalk between the pixel cells.

For example, for the blue pixel cell, the quantum efficiency value of the pixel cell having the isolation structure formed of the color filter material with a height of 0.2 μm is increased by 0.010 as compared to the pixel cell having the same isolation structure formed of tungsten. For the green pixel cell, the quantum efficiency value of the pixel cell having the isolation structure formed of the color filter material with a height of 0.2 μm was not increased but decreased by 0.016, as compared to the pixel cell having the same isolation structure formed of tungsten. That is, a level of crosstalk is maintained between the pixel cells having the isolation structure formed of the color filter material with a height of 0.2 a m, as compared to the pixel cell having the same isolation structure formed of tungsten.

For example, for the blue pixel cell, the quantum efficiency value of the pixel cell having the isolation structure formed of the color filter material with a height of 0.3 μm is increased by 0.013, as compared to the pixel cell having the same isolation structure formed of tungsten. For the green pixel cell, the quantum efficiency value of the pixel cell having the isolation structure formed of the color filter material with a height of 0.3 μm is not increased but decreased by 0.018. That is, a level of crosstalk is maintained between the pixel cells having the isolation structure formed of the color filter material with a height of 0.3 μm, as compared to the pixel cell having the same isolation structure formed of tungsten.

Since the experiment was made by using the incident light of 620 nm, and the wavelength band is red light, the quantum efficiency value of the red pixel cell shown in the third row of Table 4 represents the sensitivity of the group of pixel cells to red light. As is clear from the experiment results, the quantum efficiency increases as the height of the isolation structure decreases.

In the above experiment, for the red pixel cell, the quantum efficiency of the pixel cell having the isolation structure formed of the color filter material with a height of 0.3 μm was increased by 0.008, as compared to the pixel cell having the isolation structure formed of tungsten. Meanwhile, as described above, for the blue pixel cell, the quantum efficiency value of the pixel cell having the isolation structure formed of the color filter material with a height of 0.3 μm is increased by 0.013, as compared to the pixel cell having the same isolation structure formed of tungsten. For the green pixel cell, the quantum efficiency value of the pixel cell having the isolation structure formed of the color filter material with a height of 0.3 μm is not increased. That is, the group of pixel cells having the isolation structure formed of the color filter material with a height of 0.3 μm improves the sensitivity of the group of pixel cells to red light while maintaining the level of crosstalk, as compared to the group of pixel cells having the isolation structure formed of tungsten.

In the above experiment, for the red pixel cell, the quantum efficiency of the pixel cell having the isolation structure formed of the color filter material with a height of 0.2 μm was increased by 0.039, as compared to the pixel cell having the isolation structure formed of tungsten. Meanwhile, as described above, the quantum efficiency of the blue pixel cell having the isolation structure formed of the color filter material with a height of 0.2 μm is increased by only 0.010, and the quantum efficiency of the green pixel cell having the isolation structure formed of the color filter material with a height of 0.2 μm is not increased, as compared to the pixel cell having the isolation structure formed of tungsten. That is, the group of pixel cells having the isolation structure formed of the color filter material with a height of 0.2 μm improves the sensitivity of the group of pixel cells to red light while maintaining the level of crosstalk, as compared to the group of pixel cells having the isolation structure formed of tungsten.

Therefore, in order to balance sensitivity and crosstalk condition, an isolation structure formed of a color filter material with a height of 0.2 μm may be selected for the isolation structure around the red pixel cell.

TABLE 4

| | | 0.2 μm-color | 0.3 μm-color | 0.4 μm-color | 0.5 μm-color |
|---|---|---|---|---|---|
| | | filter | filter | filter | filter |
| | 0.23 μm-tungsten | material | material | material | material |
| Quantum efficiency | 0.030 | 0.040 | 0.043 | 0.046 | 0.047 |
| (blue pixel cell) | | | | | |
| Quantum efficiency | 0.130 | 0.114 | 0.112 | 0.112 | 0.113 |
| (green pixel cell) | | | | | |
| Quantum efficiency | 0.530 | 0.569 | 0.538 | 0.510 | 0.481 |
| (red pixel cell) | | | | | |

In general, in a pixel array element in which the pixel cells are arranged in a Bayer array, since human eyes are more sensitive to green light, in order to balance between pixels of various colors, based on the above experiment results, an isolation structure formed of a red color filter material with a height of 0.2 μm may be selected, that is, the height of the isolation structure around the blue pixel cell is 0.2 μm, which ensures an increase in sensitivity of the blue pixel cell having the isolation structure formed of the color filter material. Moreover, the isolation structure formed of the blue color filter material with a height of 0.3 μm may be selected, that is, the height of the isolation structure around the red pixel cell is 0.3 μm, which ensures an increase in sensitivity of the red pixel cell having the isolation structure formed of the color filter material, while achieving a balance between the increase in sensitivity and the maintaining of the level of crosstalk for the green pixel cells.

According to an embodiment of the present invention, each pixel cell includes a color filter 102 that filters the incident light such that light of a single wavelength of transmits through the pixel cell, as shown in FIG. 2.

According to an embodiment of the present invention, each pixel cell includes, for example, a microlens 101 located on a side of the color filter for receiving the incident light, for focusing the incident light, as shown in FIG. 2.

According to an embodiment of the present invention, each pixel cell includes an anti-reflection layer 104 coupled to a side opposite to the side of the color filter for receiving the incident light, as shown in FIG. 2.

According to an embodiment of the present invention, each pixel cell includes a photodiode 106 coupled to the anti-reflection layer and for converting the incident light into an electrical signal, as shown in FIG. 2.

According to an embodiment of the present invention, each group of pixel cells further includes an isolation element 105 located between the photodiodes, as shown in FIG. 2.

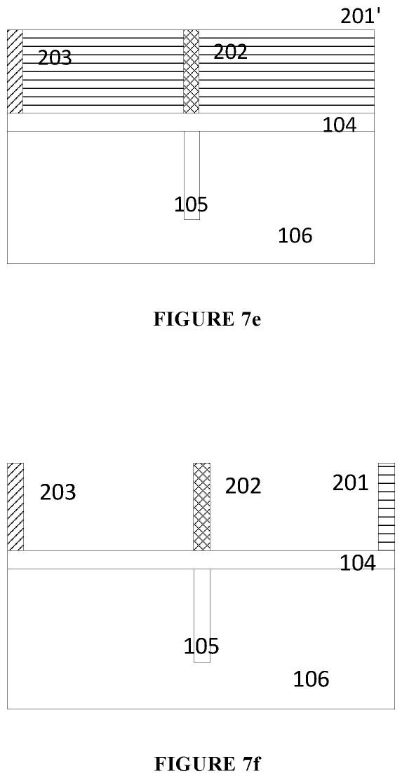

According to an embodiment of the present invention, a method of manufacturing a pixel array element is provided. As shown in FIG. 6, a flow chart of the method is shown. In step 601, there is provided a structure that comprises a plurality of photodiodes and an anti-reflection layer over the plurality of photodiodes. In step 602, there are formed a plurality of isolation structures on the anti-reflection layer, the isolation structures being spaced apart and formed of color filter materials of different colors. In step 603, there are provided color filters between the spaced apart isolation structures; wherein the color filter materials of the plurality of isolation structures have different colors from adjacent color filters.

In the method according to an embodiment of the present invention, the step of forming the plurality of isolation structures on the anti-reflection layer further comprises one or more of: coating a green color filter material on the anti-reflection layer, and forming a green isolation structure through exposure, development and baking; coating a red color filter material on the anti-reflection layer, and forming a red isolation structure through exposure, development and baking; and coating a blue color filter material on the anti-reflection layer, and forming a blue isolation structure through exposure, development and baking.

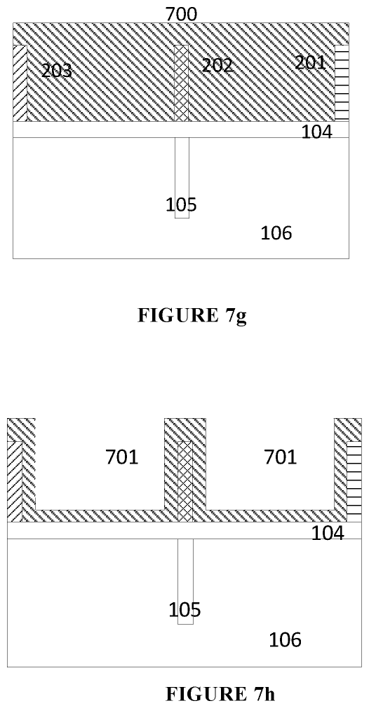

FIGS. 7a-7g illustrate schematic diagrams of manufacturing a pixel array element according to one or more exemplary embodiments of this disclosure. In FIG. 7 a-7 g, a structure is shown that comprises a plurality of photodiodes 106 and an anti-reflection layer 104 over the plurality of photodiodes. Isolation elements 105 may be comprised between the plurality of photodiodes 106.

As shown in FIGS. 7a-7b, a schematic diagram of forming a green isolation structure is shown. As shown in FIG. 7a, a green color filter material 203′ is coated on the anti-reflection layer 104. The green isolation structure 203 is formed through exposure, development and baking, as shown in FIG. 7b. As shown in FIGS. 7c-7d, schematic diagrams of forming a red isolation structure are shown. As shown in FIG. 7c, a red color filter material 202′ is coated on the anti-reflection layer. The red isolation structure 202 is formed through exposure, development and baking, as shown in FIG. 7d. Similarly, as shown in FIGS. 7e-7f, schematic diagrams of forming a blue isolation structure are shown. As shown in FIG. 7e, a blue color filter material 201′ is coated on the anti-reflection layer. The blue isolation structure 201 is formed through exposure, development and baking, as shown in FIG. 7 f.

Since the isolation structures formed of the color filter materials of different colors are formed in different steps, the heights of the isolation structures formed of the color filter materials of different colors can be conveniently set in the fabrication process of the present invention.

According to an embodiment of the present invention, the disclosed method further comprises the steps of: depositing a protective layer over the formed isolation structures; and carrying out chemical vapor deposition and etching on the deposited protective layer to form a plurality of recess structures for accommodating the color filters.

Referring to FIGS. 7g-7h, there is shown a schematic diagram of depositing a protective layer and carrying out chemical vapor deposition and etching on the deposited protective layer to form a plurality of recess structures for accommodating color filters. FIG. 7g illustrates the deposition of a protective layer 700 over the formed isolation structures. FIG. 7h shows chemical vapor deposition and etching on the deposited protective layer 700 to form a plurality of recess structures 701 for accommodating the color filters.

According to an embodiment of the present invention, in the disclosed method, the height of the isolation structure is selected such that an increased sensitivity is obtained while maintaining a level of crosstalk between the pixel cells as compared to the same isolation structure formed of tungsten.

According to an embodiment of the present invention, the disclosed method further comprises the steps of: mounting a microlens for focusing the incident light over the recess structure provided with the color filter.

In the method according to one embodiment of the present invention, an isolation element is provided between the plurality of photodiodes.

In the method according to one embodiment of the present invention, the pixel array element includes a plurality of groups of pixel cells each including a plurality of pixel cells arranged in a Bayer array, wherein an isolation structure between a red pixel cell and a green pixel cell is formed of a blue color filter material, and an isolation structure between a green pixel cell and a blue pixel cell is formed of a red color filter material.

In the method according to one embodiment of the present invention, heights of the isolation structure formed of a red color filter material and the isolation structure formed of a blue color filter material are set to different values, so that maximum sensitivities for pixel cells of different colors are obtained while maintaining a level of crosstalk between the pixel cells, as compared to the isolation structure formed of tungsten.

It should also be understood that this disclosure also contemplates the following.

Item 1. A pixel array element having an isolation structure, comprising: a plurality of groups of pixel cells each including a plurality of pixel cells having different colors, wherein the pixel cells having different colors are alternately arranged such that each pixel cell has a different color from an adjacent pixel cell; and an isolation structure located between the adjacent pixel cells and formed of a color filter material, wherein the color filter material of the isolation structure has a color different from that of the adjacent pixel cell.

Item 2. The pixel array element according to item 1, wherein each of the plurality of groups of pixel cells includes a plurality of pixel cells arranged in a Bayer array, wherein the isolation structure between a red pixel cell and a green pixel cell is formed of a blue color filter material, and the isolation structure between a green pixel cell and a blue pixel cell is formed of a red color filter material.

Item 3. The pixel array element according to item 1, wherein a height of the isolation structure is selected such that an increased sensitivity is obtained while maintaining a level of crosstalk between the pixel cells as compared to the same isolation structure formed of tungsten.

Item 4. The pixel array element according to item 3, wherein heights of the isolation structure formed of the red color filter material and the isolation structure formed of the blue color filter material are set to different values so that maximum sensitivities for the pixel cells of different colors are obtained while maintaining a level of crosstalk between the pixel cells.

Item 5. The pixel array element according to item 1, wherein each pixel cell includes a color filter that filters an incident light such that light of a single wavelength transmits through the pixel cell.

Item 6. The pixel array element according to item 5, wherein each pixel cell includes a microlens located on a side of the color filter for receiving the incident light, for focusing the incident light.

Item 7. The pixel array element according to item 5, wherein each pixel cell includes an anti-reflection layer coupled to a side opposite to the side of the color filter for receiving the incident light.

Item 8. The pixel array element according to item 7, wherein each pixel cell includes a photodiode coupled to the anti-reflection layer and for converting the incident light into an electrical signal.

Item 9. The pixel array element according to item 8, wherein each group of pixel cells further includes an isolation element located between the photodiodes.

Item 10. A method of manufacturing a pixel array element, comprising the steps of: providing a structure that comprises a plurality of photodiodes and an anti-reflection layer over the plurality of photodiodes; forming a plurality of isolation structures on the anti-reflection layer, the isolation structures being spaced apart and formed of color filter materials of different colors; and providing color filters between the spaced apart isolation structures; wherein the color filter materials of the plurality of isolation structures have different colors from adjacent color filters.

Item 11. The method according to item 10, wherein the step of forming a plurality of isolation structures on the anti-reflection layer further comprises one or more of: coating a green color filter material on the anti-reflection layer, and forming a green isolation structure through exposure, development and baking; coating a red color filter material on the anti-reflection layer, and forming a red isolation structure through exposure, development and baking; and coating a blue color filter material on the anti-reflection layer, and forming a blue isolation structure through exposure, development and baking.

Item 12. The method according to item 10, further comprising the steps of: depositing a protective layer over the formed isolation structures; and carrying out chemical vapor deposition and etching on the deposited protective layer to form a plurality of recess structures for accommodating the color filters.

Item 13. The method according to item 10, wherein heights of the isolation structures are selected such that an increased sensitivity is obtained while maintaining a level of crosstalk between the pixel cells as compared to the same isolation structure formed of tungsten.

Item 14. The method according to item 12, further comprising: mounting microlenses over the recess structures provided with the color filters, for focusing the incident light.

Item 15. The method according to item 10, wherein an isolation element is provided between the plurality of photodiodes.

Item 16. The method according to item 10, wherein the pixel array element includes a plurality of groups of pixel cells each including a plurality of pixel cells arranged in a Bayer array, wherein an isolation structure between a red pixel cell and a green pixel cell is formed of a blue color filter material, and an isolation structure between a green pixel cell and a blue pixel cell is formed of a red color filter material.

Item 17. The method according to claim 16, heights of the isolation structure formed of a red color filter material and the isolation structure formed of a blue color filter material are set to different values, so that maximum sensitivities for the pixel cells of different colors are obtained while maintaining a level of crosstalk between the pixel cells, as compared to the isolation structure formed of tungsten.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of this disclosure have been described in detail with examples, it should be understood by a person skilled in the art that the above examples are only intended to be illustrative but not to limit the scope of this disclosure. The embodiments disclosed herein can be combined arbitrarily with each other, without departing from the scope and spirit of this disclosure. It should be understood by a person skilled in the art that the above embodiments can be modified without departing from the scope and spirit of this disclosure. The scope of this disclosure is defined by the attached claims.

What is claimed is:

1. A pixel array element having an isolation structure, comprising:
a plurality of groups of pixel cells each including a plurality of pixel cells having different colors, wherein the pixel cells having different colors are alternately arranged such that each pixel cell has a different color from an adjacent pixel cell; and
an isolation structure located between the adjacent pixel cells and formed of a color filter material, wherein the color filter material of the isolation structure has a color different from that of the adjacent pixel cell.

2. The pixel array element according to claim 1, wherein each of the plurality of groups of pixel cells includes a plurality of pixel cells arranged in a Bayer array, wherein the isolation structure between a red pixel cell and a green pixel cell is formed of a blue color filter material, and the isolation structure between a green pixel cell and a blue pixel cell is formed of a red color filter material.

3. The pixel array element according to claim 1, wherein a height of the isolation structure is selected such that an increased sensitivity is obtained while maintaining a level of crosstalk between the pixel cells as compared to the same isolation structure formed of tungsten.

4. The pixel array element according to claim 3, wherein heights of the isolation structure formed of the red color filter material and the isolation structure formed of the blue color filter material are set to different values so that maximum sensitivities for the pixel cells of different colors are obtained while maintaining a level of crosstalk between the pixel cells.

5. The pixel array element according to claim 1, wherein each pixel cell includes a color filter that filters an incident light such that light of a single wavelength transmits through the pixel cell.

6. The pixel array element according to claim 5, wherein each pixel cell includes a microlens located on a side of the color filter for receiving the incident light, for focusing the incident light.

7. The pixel array element according to claim 5, wherein each pixel cell includes an anti-reflection layer coupled to a side opposite to the side of the color filter for receiving the incident light.

8. The pixel array element according to claim 7, wherein each pixel cell includes a photodiode coupled to the anti-reflection layer and for converting the incident light into an electrical signal.

9. The pixel array element according to claim 8, wherein each group of pixel cells further includes an isolation element located between the photodiodes.

10. A method of manufacturing a pixel array element, comprising the steps of:
providing a structure that comprises a plurality of photodiodes and an anti-reflection layer over the plurality of photodiodes;
forming a plurality of isolation structures on the anti-reflection layer, the isolation structures being spaced apart and formed of color filter materials of different colors; and
providing color filters between the spaced apart isolation structures;
wherein the color filter materials of the plurality of isolation structures have different colors from adjacent color filters.

11. The method according to claim 10, wherein the step of forming a plurality of isolation structures on the anti-reflection layer further comprises one or more of:
coating a green color filter material on the anti-reflection layer, and forming a green isolation structure through exposure, development and baking;
coating a red color filter material on the anti-reflection layer, and forming a red isolation structure through exposure, development and baking; and
coating a blue color filter material on the anti-reflection layer, and forming a blue isolation structure through exposure, development and baking.

12. The method according to claim 10, further comprising the steps of:
depositing a protective layer over the formed isolation structures; and
carrying out chemical vapor deposition and etching on the deposited protective layer to form a plurality of recess structures for accommodating the color filters.

13. The method according to claim 10, wherein heights of the isolation structures are selected such that an increased sensitivity is obtained while maintaining a level of crosstalk between the pixel cells as compared to the same isolation structure formed of tungsten.

14. The method according to claim 12, further comprising:
mounting microlenses over the recess structures provided with the color filters, for focusing the incident light.

15. The method according to claim 10, wherein an isolation element is provided between the plurality of photodiodes.

16. The method according to claim 10, wherein the pixel array element includes a plurality of groups of pixel cells each including a plurality of pixel cells arranged in a Bayer array, wherein an isolation structure between a red pixel cell and a green pixel cell is formed of a blue color filter material, and an isolation structure between a green pixel cell and a blue pixel cell is formed of a red color filter material.

17. The method according to claim 16, heights of the isolation structure formed of a red color filter material and the isolation structure formed of a blue color filter material are set to different values, so that maximum sensitivities for the pixel cells of different colors are obtained while maintaining a level of crosstalk between the pixel cells, as compared to the isolation structure formed of tungsten.
